(19) United States
(12) Patent Application Publication
(10) Pub. No.: US 2026/0293607 A1
(43) Pub. Date: Sep. 24, 2026

(54) WAFER PROCESSING APPARATUS AND WAFER HOLDING DEVICE THEREOF

(71) Applicant: ProAsia Semiconductor Corporation, Hsinchu City (TW)

(72) Inventor: Yun-Shen Li, Hsinchu City (TW)

(21) Appl. No.: 19/562,227

(22) Filed: Mar. 10, 2026

(30) Foreign Application Priority Data
Mar. 24, 2025 (TW) 114111052

(51) Int. Cl. H10P 72/76

(52) U.S. Cl. CPC H10P 72/7608

(57) ABSTRACT

A wafer holding device, including a support platform, a plurality of holding assemblies, and a driving unit, is provided. The holding assemblies are arranged on the support platform, and each includes a base, a first magnetic element disposed on the base, and an elastic element with two ends respectively abutting against the base and the support platform. The driving unit includes a movable element and at least one second magnetic element disposed on the movable element. By moving the movable element relative to the support platform, the at least one second magnetic element is brought to approach or move away from the first magnetic element of each holding assembly, thereby driving the base of each holding assembly to move to release the wafer and compress the elastic element, or driving the base to hold the wafer through the elastic restoring force of the elastic element of each holding assembly.

### CROSS-REFERENCES TO RELATED APPLICATIONS

This application claims priority to Taiwan Patent Application No. 114111052 filed on March 24, 2025, which is hereby incorporated by reference in its entirety.

### BACKGROUND OF THE INVENTION

### Field of the Invention

The present invention relates to wafer holding technology, in particular to a wafer holding device utilizing magnetic elements in combination with elastic elements for control, and a wafer processing apparatus using the device.

### Descriptions of the Related Art

Wafer holding devices are widely applied in single-wafer processing apparatus, such as wafer etching apparatus, wafer cleaning apparatus or similar apparatus. Most of conventional wafer holding devices are designed to use springs in combination with cam drive components. They mainly move the cam drive component to abut against the inclined surface member of the clamp, thereby driving the clamp to release the wafer from its holding state. The cam drive component is then moved in the opposite direction to drive the clamp to hold the wafer using the spring force of the spring. However, after prolonged use, the inclined surface of the inclined surface member is susceptible to wear, resulting in problems such as irregular driving of clamp or inability of the clamp to hold the wafer tightly. In addition, conventional wafer holding devices typically employ linkage mechanism coupled with springs for actuation. However, during the driving process, the linkage mechanism is prone to structural interference with other structural members of the clamp, causing a delay in the actuation of the clamp.

Therefore, it is worthwhile to study how to design a wafer holding device that can solve the above problems.

### SUMMARY OF THE INVENTION

The objective of the present invention is to provide a wafer holding device in which magnetic elements are combined with elastic elements for control.

To achieve the above objectives, the wafer holding device of the present invention includes a support platform, a plurality of holding assemblies and a driving unit. The support platform includes a first side and a second side opposite to each other. The holding assemblies are arranged on the support platform, and each holding assembly includes a base, a first magnetic element, and an elastic element. The base is movable relative to the support platform. The first magnetic element is disposed on the base, and two ends of the elastic element are respectively in contact with the base and the support platform. The driving unit includes a movable element and at least one second magnetic element. The movable element is movable relative to the support platform. The at least one second magnetic element is disposed on the movable element. When the movable element approaches the second side of the support platform, the first magnetic element of each of the holding assemblies is driven by the at least one second magnetic element to bring the base of each of the holding assemblies to release clamping of the wafer and compress the elastic element. When the movable element moves away from the second side of the support platform, the base is driven to hold the wafer by an elastic restoring force of the elastic element of each of the holding assemblies.

In an embodiment of the present invention, the support platform further includes a plurality of guide holes, and each of the guide holes passes through from the first side to the second side. The base comprises a first component, a second component and a guide element. The first component is connected to the second component via the guide element. The guide element passes through the corresponding guide hole and is movable linearly in the guide hole. The first component is located on the first side, and the second component is located on the second side.

In an embodiment of the present invention, the base further comprises a third component, wherein the third component is located on the second side and is adjustably coupled to the second component, and the first magnetic element is disposed on the third component.

In an embodiment of the present invention, the support platform further includes a plurality of slide grooves, each of the slide grooves is disposed on the first side. Each of the guide holes passes through from a bottom surface of a corresponding slide groove to the second side. The base further comprises a sliding block, the sliding block is disposed on the first component and slides linearly in the corresponding slide groove.

In an embodiment of the present invention, the support platform further includes a flow guide portion, the flow guide portion is provided on the first side, and a fluid passage is formed between the flow guide portion and a surface of the first side.

In an embodiment of the present invention, the base further includes a holding portion and a supporting portion, wherein both the holding portion and the supporting portion are disposed on the first component.

In an embodiment of the present invention, the support platform further includes a plurality of accommodating portions, and the base of each of the holding assemblies further includes a corresponding accommodating portion, wherein the two ends of the elastic element of each of the holding assemblies are respectively engaged with one of the plurality of accommodating portions and the corresponding accommodating portion of the base.

In an embodiment of the present invention, the wafer holding device further includes a plurality of quick-release elements, wherein each of the quick-release elements is disposed on the second side and allows the corresponding elastic element to be held between the quick-release element and the support platform.

In an embodiment of the present invention, a first active surface of the first magnetic element and a second active surface of the at least one second magnetic element have the same polarity, and the first magnetic element is farther from a central axis of the support platform than the at least one second magnetic element.

In an embodiment of the present invention, a first active surface of the first magnetic element and a second active surface of the at least one second magnetic element have the opposite polarities, and the first magnetic element is closer to a central axis of the support platform than the at least one second magnetic element.

In an embodiment of the present invention, the elastic element is a flat spring.

The present invention further includes a wafer processing apparatus using the aforementioned wafer holding device.

### BRIEF DESCRIPTION OF THE DRAWINGS

FIG. 1 is a schematic view of a wafer holding device according to the present invention.

FIG. 2 is a top view of the wafer holding device of the present invention.

FIG. 3 is a top view of the support platform of the wafer holding device of the present invention.

FIG. 4 is an exploded view of a holding assembly of the wafer holding device of the present invention.

FIG. 5 is a cross-sectional view along line A-A' in FIG. 2.

FIG. 6 is a top view of the arrangement of the elastic element of a holding assembly of the wafer holding device of the present invention.

FIG. 7 is a schematic view showing that the wafer holding device according to the present invention is operated to hold a wafer.

FIG. 8 is a schematic view showing that the wafer holding device according to the present invention is operated to release the holding of the wafer.

FIG. 9 is a schematic view showing that the wafer holding device in another embodiment according to the present invention is operated to hold the wafer.

FIG. 10 is a schematic view showing that the wafer holding device in another embodiment according to the present invention is operated to release the holding of the wafer.

### DETAILED DESCRIPTION OF THE PREFERRED EMBODIMENT

Since the various aspects and embodiments are merely illustrative and not restrictive, after reading this specification, a person having ordinary skill in the art may also have other aspects and embodiments without departing from the scope of the present invention. The features and advantages of these embodiments and the scope of the patent application will be better appreciated from the following detailed description.

Herein, the terms "a" or "an" is used to describe one or more devices and components described herein. Such a descriptive term is merely for the convenience of illustration and to provide a general sense of the scope of the present invention. Therefore, unless expressly stated otherwise, the term "a" or "an” is to be understood to include one or at least one, and the singular form also includes the plural form.

Herein, the terms "first" or "second" and similar ordinal numbers are mainly used to distinguish or refer to the same or similar devices or structures, and do not necessarily imply the spatial or temporal order of such devices or structures. It should be understood that in certain situations or configurations, ordinal numbers may be used interchangeably without affecting the practice of the present invention.

As used herein, the terms “comprise”, "include", “have" or any other similar term is not intended to exclude additional, unrecited elements. For example, a device or structure comprising, including, or having a plurality of elements is not solely limited to the elements listed herein but may further comprise, include, or have other elements not explicitly listed but generally inherent to the device or structure.

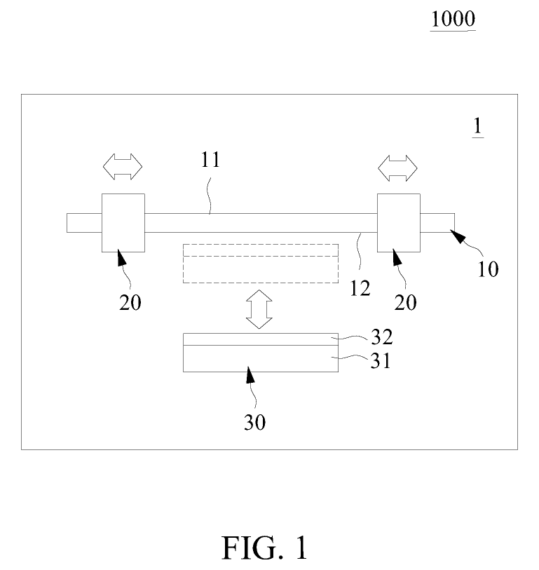

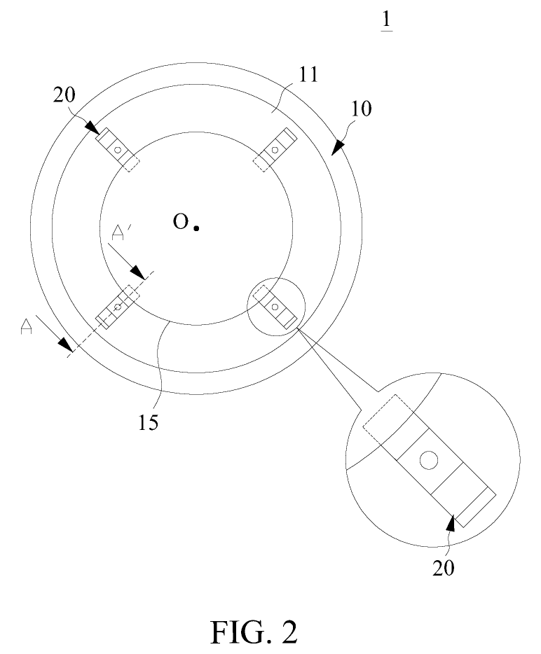

Please refer to FIG. 1 and FIG. 2 together. FIG. 1 is a schematic view of a wafer holding device 1 according to the present invention. FIG. 2 is a top view of the wafer holding device 1 of the present invention. As shown in FIG. 1 and FIG. 2, the wafer holding device 1 of the present invention is applied to a wafer processing apparatus 1000, e.g., a wafer etching apparatus, a wafer cleaning apparatus or other similar apparatus. The wafer holding device 1 of the present invention includes a support platform 10, a plurality of holding assemblies 20, and a driving unit 30. The support platform 10 includes a first side 11 and a second side 12 opposite to each other. The wafer is mainly secured to the first side 11 of the support platform 10, so as to facilitate corresponding processing procedures on the wafer.

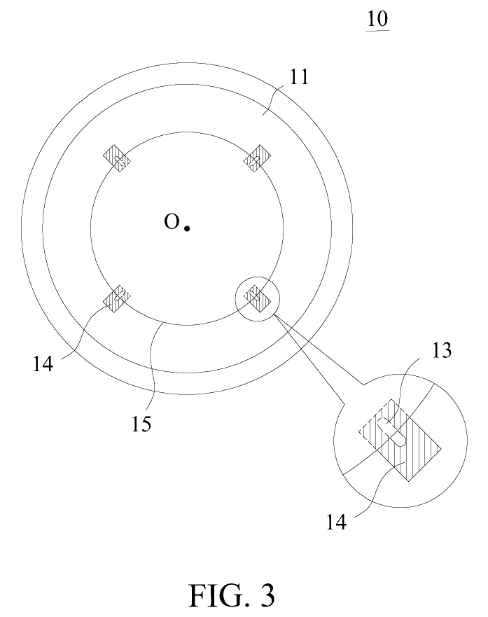

Please refer to FIG. 1 and FIG. 3 together. FIG. 3 is a top view of the support platform 10 of the wafer holding device 1 of the present invention. As shown in FIGS. 1 and 3, in an embodiment of the present invention, the support platform 10 further includes a plurality of guide holes 13. Each guide hole 13 passes through from the first side 11 to the second side 12, and each guide hole 13 is an elongated hole. The number and positions of the plurality of guide holes 13 will be adjusted based on the number and positions of the plurality of holding assemblies 20.

In an embodiment of the present invention, the support platform 10 further includes a plurality of slide grooves 14. Each slide groove 14 is disposed on the first side 11, and each guide hole 13 passes through from the bottom surface of the corresponding slide groove 14 to the second side 12. The number and position of the plurality of slide grooves 14 are adjusted based on the number and position of the plurality of holding assemblies 20.

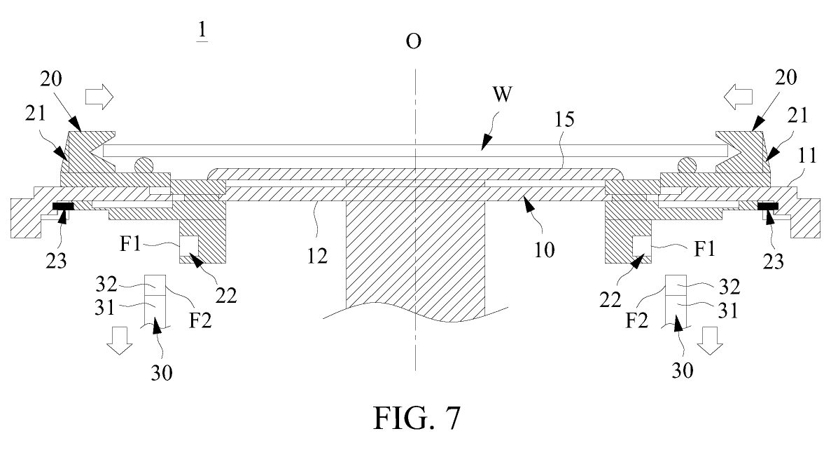

In an embodiment of the present invention, the support platform 10 further includes a flow guide portion 15, which provides a flow guide function for fluids, such as solutions used in wafer processing processes. The flow guide portion 15 is disposed on the first side 11, and a fluid passage is formed between the flow guide portion 15 and the surface of the first side 11 (please also refer to FIG. 7 to FIG. 10). In addition, based on the design of the flow guide portion 15, a liquid discharge structure (not shown, such as a liquid discharge hole, etc.) may be further provided on the support platform 10 to accelerate the discharge of liquid from the support platform. In one embodiment of the present invention, the flow guide portion 15 partially covers each guide hole 13 and each slide groove 14, such that when the plurality of holding assemblies 20 are subsequently disposed, the flow guide portion 15 can provide an auxiliary position-limiting effect for the plurality of holding assemblies 20, but the present invention is not limited thereto.

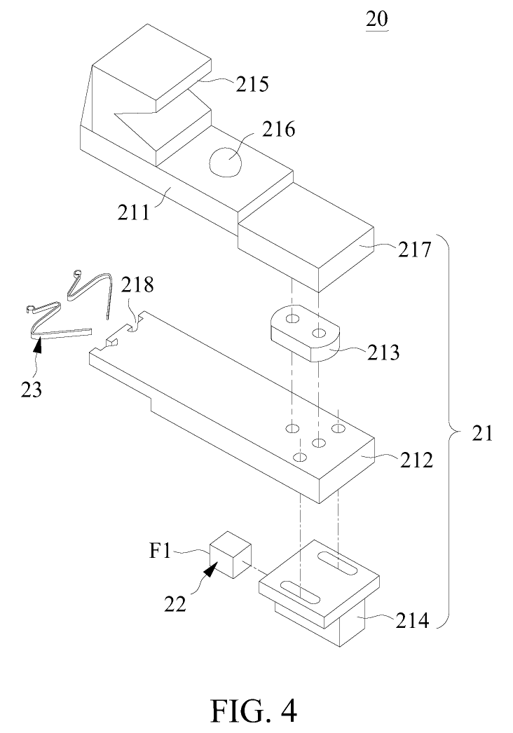

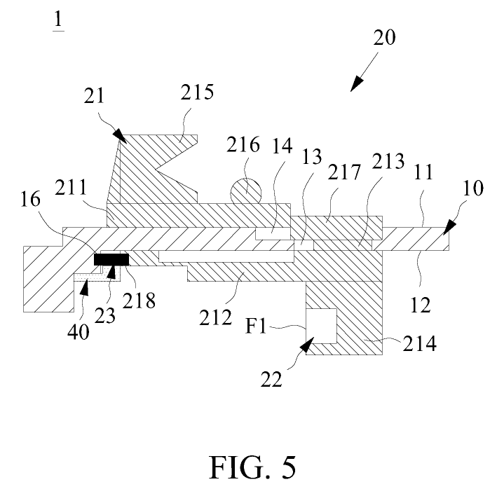

Please refer to FIGS. 1, 2, 4 and 5. FIG. 4 is an exploded view of a holding assembly 20 of the wafer holding device 1 of the present invention. FIG. 5 is a cross-sectional view along line A-A' in FIG. 2. As shown in FIG. 1, FIG. 2, FIG. 4 and FIG. 5, the plurality of holding assemblies 20 are disposed on the support platform 10 to provide the function of holding or releasing the wafer. Each holding assembly 20 includes a base 21, a first magnetic element 22, and an elastic element 23. The base 21 is movable relative to the support platform 10 along a straight line. The first magnetic element 22 is disposed on the base 21 to serve as a power source for driving the base 21 to move. Two ends of the elastic element 23 abut against the base 21 and the support platform 10, respectively, to serve as another power source for driving the base 21 to move. When the base 21 moves relative to the support platform 10, it not only drives the first magnetic element 22 to move, but also causes the elastic element 23 to be in a compressed state or a relaxed state as the distance between the base 21 and the support platform 10 changes.

In one embodiment of the present invention, the base 21 includes a first component 211, a second component 212, and a guide element 213, and the first component 211 is connected to the second component 212 via the guide element 213. In other words, the guide element 213 is sandwiched between the first component 211 and the second component 212. The first component 211 is located on the first side 11, and the second component 212 is located on the second side 12. The guide element 213 passes through the corresponding guide hole 13 and is movable linearly along the guide hole 13. In an embodiment of the present invention, the first component 211, the second component 212, and the guide element 213 can be secured to one another by screws and holes correspondingly arranged, but the manner in which these components are coupled is not limited thereto. For example, these components can also be formed as a single integrated piece by an integral molding process.

In one embodiment of the present invention, the base 21 further includes a third component 214. The third component 214 is disposed on the second component 212 and is configured for embedding and securing the first magnetic element 22 therein. The third component 214 is located on the second side 12. In an embodiment of the present invention, the third component 214 can be secured to the second component 212 by screws and slots correspondingly arranged. The third component 214 is adjustable in its coupling position relative to the second component 212 to change the magnetic actuation position or distance of the first magnetic element 22, but the coupling manner of the second component 212 and the third component 214 is not limited thereto. For example, the second component 212 and the third component 214 can also be formed as a single integrated piece by an integral molding process.

In one embodiment of the present invention, the base 21 further includes a holding portion 215. The holding portion 215 is disposed on the first component 211 and is configured to hold the wafer located on the first side 11. The holding portion 215 is located on the first side 11.

In an embodiment of the present invention, the base 21 further includes a supporting portion 216. The supporting portion 216 is disposed on the first component 211 and is configured to support the wafer located on the first side 11. The supporting portion 216 is located on the first side 11.

In an embodiment of the present invention, the base 21 further includes a sliding block 217. The sliding block 217 is disposed on the first component 211 and is located within the corresponding slide groove 14, such that the sliding block 217 moves linearly along the slide groove 14 when the base 21 moves. The sliding block 217 is located on the first side 11.

In an embodiment of the present invention, the first magnetic element 22 is disposed on the third component 214. The first magnetic element 22 is a single magnet. The first magnetic element 22 includes a first active surface F1, and the first active surface F1 of the first magnetic element 22 is exposed from the third component 214. The polarity of the first active surface F1 of the first magnetic element 22 may vary depending on different designs or requirements.

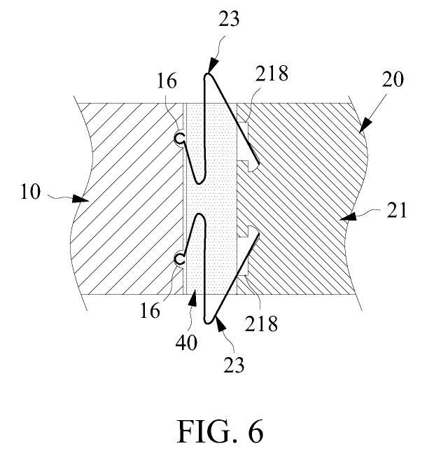

Please refer to FIG. 2, FIG. 4, FIG. 5 and FIG. 6 together. FIG. 6 is a top view of the arrangement of the elastic element 23 of a holding assembly 20 of the wafer holding device 1 of the present invention. As shown in FIG. 2, FIG. 4, FIG. 5, and FIG. 6, in an embodiment of the present invention, the support platform 10 further includes a plurality of accommodating portions 16. Each accommodating portion 16 is disposed on the second side 12. The number and positions of the plurality of accommodating portions 16 are adjusted based on the number and positions of the plurality of holding assemblies 20. In an embodiment of the present invention, the base 21 of each holding assembly 20 further includes a corresponding accommodating portion 218. The corresponding accommodating portion 218 is disposed on the second component 212, and the location of the corresponding accommodating portion 218 corresponds to the location of one of the accommodating portions 16 of the support platform 10. The corresponding accommodating portion 218 is located on the second side 12.

The two ends of the elastic element 23 of each holding assembly 20 respectively abut and are engaged with one of the plurality of accommodating portions 16 of the support platform 10 and the corresponding accommodating portion 218 of the base 21. When the base 21 is driven and approaches the support platform 10, the elastic element 23 is gradually compressed into a compressed state. When the elastic element 23 is released from the compressed state, the elastic element 23 generates an elastic restoring force to push the base 21 relative to the support platform 10, eventually bringing the elastic element 23 into a relaxed state. In an embodiment of the present invention, the elastic element 23 is a flat spring, but the form of the elastic element 23 is not limited thereto.

In an embodiment of the present invention, the wafer holding device 1 further includes a plurality of quick-release elements 40. Each quick-release element 40 is disposed on the second side 12 and allows the elastic element 23 of the corresponding holding assembly 20 to be sandwiched between the quick-release element 40 and the support platform 10. Each quick-release element 40 is configured to support and secure the elastic element 23 of the corresponding holding assembly 20. When the elastic element 23 of any holding assembly 20 needs to be replaced, the user can quickly and conveniently replace the elastic element 23 by removing the corresponding quick-release element 40. The number and positions of the plurality of quick-release elements 40 are adjusted based on the number and positions of the holding assemblies 20.

Furthermore, as shown in FIG. 1, the driving unit 30 includes a movable element 31 and at least one second magnetic element 32. The movable element 31 is movable linearly relative to the support platform 10 to approach or move away from the second side 12 of the support platform 10. The at least one second magnetic element 32 is disposed on the movable element 31, such that the at least one second magnetic element 32 gradually approaches or moves away from the second side 12 of the support platform 10 as the movable element 31 moves. The location of the at least one second magnetic element 32 corresponds to that of the first magnetic element 22 of each holding assembly 20. In an embodiment of the present invention, the at least one second magnetic element 32 is a single magnetic ring, but the present invention is not limited thereto. The at least one second magnetic element 32 may also be a plurality of magnets. Each second magnetic element 32 includes a second active surface F2 (please also refer to FIG. 7 to FIG. 10). The polarity of the second active surface F2 of the second magnetic element 32 may vary depending on different designs or requirements.

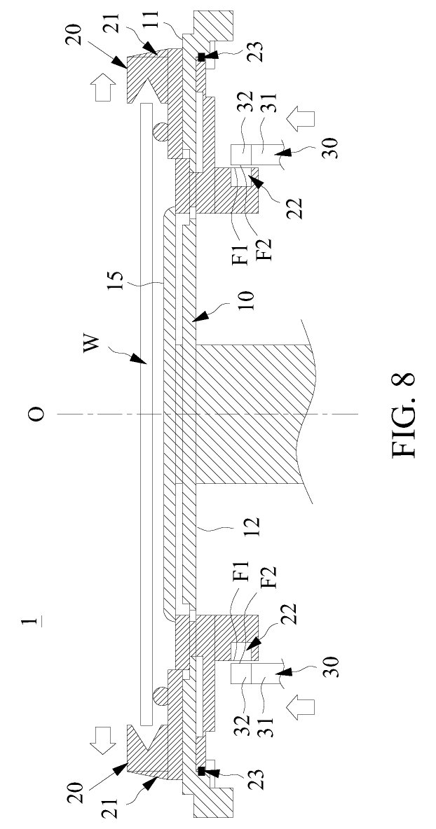

The operating principle of the wafer holding device 1 of the present invention will be described below with reference to different embodiments. It should be noted that, in the following description, only the operation of one of the plurality of holding assemblies 20 in conjunction with other components is presented, while the other holding assemblies 20 operate based on the same operating principle. Please refer to FIG. 2, FIG. 7 and FIG. 8 together. FIG. 7 is a schematic view showing that the wafer holding device according to the present invention is operated to hold a wafer. FIG. 8 is a schematic view showing that the wafer holding device according to the present invention is operated to release the holding of the wafer. As shown in FIG. 2, FIG. 7 and FIG. 8, in this embodiment, it is assumed that the wafer holding device 1 of the present invention includes four holding assemblies 20, and the holding assemblies 20 are symmetrically arranged relative to the central axis O of the support platform 10. The base 21 of each holding assembly 20 is movable along a straight line. The movable element 31 of the driving unit 30 moves linearly along the central axis O of the support platform 10. In other words, the moving direction of the movable element 31 is perpendicular to the moving direction of the base 21 of each holding assembly 20. The wafer holding device 1 of the present invention holds the wafer W by the holding portion 215 of each holding assembly 20 and supports the wafer W by the supporting portion 216 of each holding assembly 20.

In an embodiment of the present invention, the first active surface F1 of the first magnetic element 22 of each holding assembly 20 and the second active surface F2 of the at least one second magnetic element 32 have opposite polarities. In terms of structural design, the first magnetic element 22 is closer to the central axis O of the support platform 10 than the at least one second magnetic element 32. That is, if the central axis O is used as a reference (the center of a circle), the first magnetic element 22 of each holding assembly 20 will be arranged at a position closer to an inner radial position, and the at least one second magnetic element 32 will be arranged at a position closer to an outer radial position.

For example, in this embodiment, the first active surface F1 of the first magnetic element 22 of each holding assembly 20 is a north pole (or alternatively, a south pole), and the second active surface F2 of at least one second magnetic element 32 is a south pole (or alternatively, a north pole). When the movable element 31 gradually approaches the second side 12 of the support platform 10, the second active surface F2 of at least one second magnetic element 32 will also gradually approach the first active surface F1 of the first magnetic element 22 of each holding assembly 20, and finally the second active surface F2 of at least one second magnetic element 32 and the first active surface F1 of the first magnetic element 22 of each holding assembly 20 are located on the same horizontal plane. At this time, a magnetic attraction force is generated between the first magnetic element 22 of each holding assembly 20 and the at least one second magnetic element 32, thereby driving the base 21 of each holding assembly 20 to move linearly in a direction away from the central axis O of the support platform 10, thus releasing the holding of the wafer W. The final state is as shown in FIG. 8. During the movement of the base 21 of each holding assembly 20, the corresponding elastic element 23 is gradually compressed.

Conversely, when the movable element 31 gradually moves away from the second side 12 of the support platform 10, the second active surface F2 of the at least one second magnetic element 32 will also gradually move away from the first active surface F1 of the first magnetic element 22 of each holding assembly 20, thereby causing the magnetic attraction force between the first magnetic element 22 of each holding assembly 20 and the at least one second magnetic element 32 to disappear. At this time, the elastic element 23 in a compressed state of each holding assembly 20 generates an elastic restoring force to gradually drive the base 21 of each holding assembly 20 to move linearly in a direction toward the central axis O of the support platform 10, thereby holding the wafer W. The final state is as shown in FIG. 7.

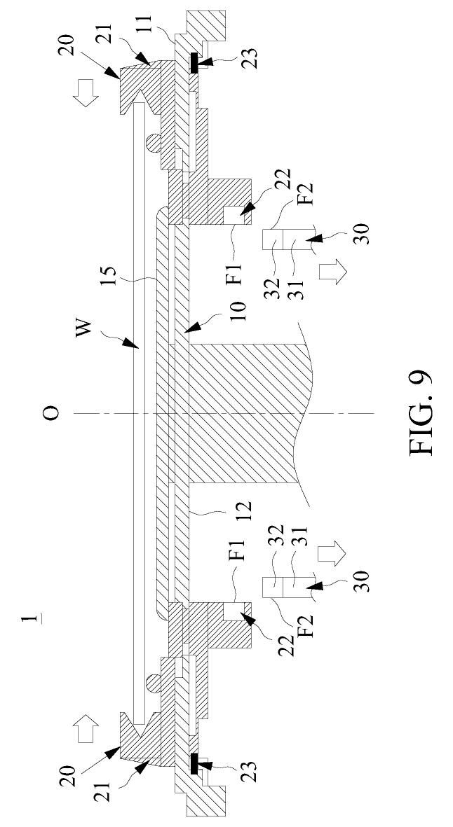

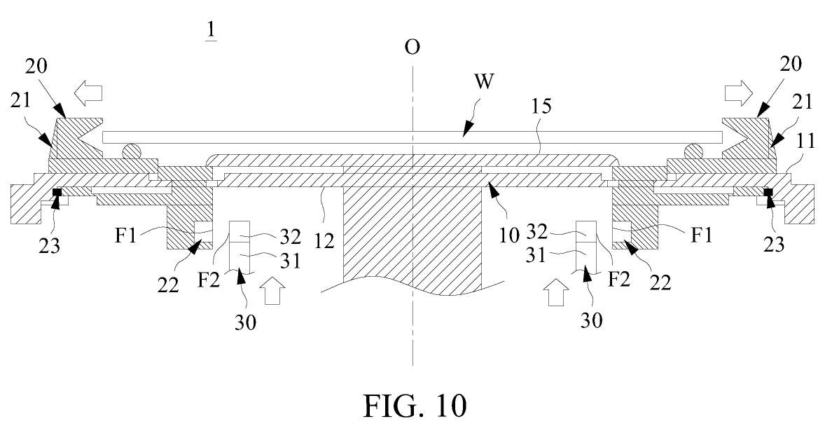

Please refer to FIG. 2, FIG. 9 and FIG. 10 together. FIG. 9 is a schematic view showing that the wafer holding device in another embodiment according to the present invention is operated to hold the wafer. FIG. 10 is a schematic view showing that the wafer holding device in another embodiment according to the present invention is operated to release the holding of the wafer. As shown in FIG. 2, FIG. 9 and FIG. 10, in this embodiment (another embodiment of the present invention), the first active surface F1 of the first magnetic element 22 of each holding assembly 20 and the second active surface F2 of at least one second magnetic element 32 have the same polarity. In terms of structural design, the first magnetic element 22 is farther from the central axis O of the support platform 10 than the at least one second magnetic element 32. That is, if the central axis O is used as a reference (the center of a circle), the first magnetic element 22 of each holding assembly 20 will be arranged at a position closer to the outer radial position, and the at least one second magnetic element 32 will be arranged at a position closer to the inner radial position.

For example, in this embodiment, the first active surface F1 of the first magnetic element 22 of each holding assembly 20 and the second active surface F2 of at least one second magnetic element 32 are both north poles or south poles. When the movable element 31 gradually approaches the second side 12 of the support platform 10, the second active surface F2 of at least one second magnetic element 32 will also gradually approach the first active surface F1 of the first magnetic element 22 of each holding assembly 20, and finally the second active surface F2 of at least one second magnetic element 32 and the first active surface F1 of the first magnetic element 22 of each holding assembly 20 are located on the same horizontal plane. At this time, a magnetic repulsive force is generated between the first magnetic element 22 of each holding assembly 20 and the at least one second magnetic element 32, thereby driving the base 21 of each holding assembly 20 to move linearly in a direction away from the central axis O of the support platform 10, thus releasing the holding of the wafer W. The final state is as shown in FIG. 10. During the movement of the base 21 of each holding assembly 20, the corresponding elastic element 23 is gradually compressed.

Conversely, when the movable element 31 gradually moves away from the second side 12 of the support platform 10, the second active surface F2 of the at least one second magnetic element 32 will also gradually move away from the first active surface F1 of the first magnetic element 22 of each holding assembly 20, thereby causing the magnetic repulsive force between the first magnetic element 22 of each holding assembly 20 and the at least one second magnetic element 32 to disappear. At this time, the elastic element 23 in a compressed state of each holding assembly 20 generates an elastic restoring force to gradually drive the base 21 of each holding assembly 20 to move linearly in a direction toward the central axis O of the support platform 10, thereby holding the wafer W. The final state is as shown in FIG. 9.

Accordingly, the wafer holding device 1 of the present invention can switch between the functions of holding the wafer and releasing the wafer from holding by changing the position of the movable element 31 of the driving unit 30 in cooperation with the arrangement of the elastic elements and magnetic elements.

In addition, as shown in FIG. 1, the present invention further includes a wafer processing apparatus 1000 using the aforementioned wafer holding device 1. The wafer processing apparatus 1000 of the present invention holds a wafer using the wafer holding device 1 to facilitate corresponding processing procedures on the wafer. For example, when the wafer processing apparatus 1000 of the present invention is a wafer cleaning apparatus, the wafer is first held by the plurality of holding assemblies 20 of the wafer holding device 1, and then the cleaning liquid is sprayed on the wafer and rotated about the central axis O of the support platform 10, thereby achieving an effective cleaning effect. In addition, the design of the flow guide portion 15 of the support platform 10 of the wafer holding device 1 can further provide fluid guiding and discharge effects.

In summary, the wafer holding device of the present invention controls the holding state of the wafer through the combination of magnetic elements and elastic elements, thereby reducing structural wear and interference that may easily occur between related components, and improving issues such as irregular driving of the clamp, inability of the clamp to hold the wafer tightly, or delayed actuation of the clamp.

The foregoing detailed description is illustrative in nature only and is not intended to limit the embodiments of the claimed subject matters or the applications or uses of such embodiments. Furthermore, while at least one exemplary embodiment has been presented in the foregoing detailed description, it should be appreciated that a wide variety of modifications to the present invention are possible. It should also be appreciated that the embodiments described herein are not intended to limit the scope, use, or configuration of the claimed subject matters in any way. Instead, the foregoing detailed description is intended to provide a person having ordinary skill in the art with a convenient guide for implementing one or more of the described embodiments. Moreover, various modifications may be made to the function and arrangement of the devices without departing from the scope defined by the claims, including known equivalents and any equivalents that may be anticipated at the time of filing this patent application.

What is claimed is:

1. A wafer holding device for holding a wafer, the wafer holding device comprising:
a support platform comprising a first side and a second side opposite to each other;
a plurality of holding assemblies arranged on the support platform, each of the plurality of holding assemblies comprising a base, a first magnetic element, and an elastic element, the base being movable relative to the support platform, the first magnetic element being disposed on the base, and two ends of the elastic element respectively abutting against the base and the support platform; and
a driving unit comprising a movable element and at least one second magnetic element, the movable element being movable relative to the support platform, and the at least one second magnetic element being disposed on the movable element;
wherein when the movable element approaches the second side of the support platform, the first magnetic element of each of the holding assemblies is driven by the at least one second magnetic element to bring the base of each of the holding assemblies to release the holding of the wafer and compress the elastic element; and wherein when the movable element moves away from the second side of the support platform, the base is driven to hold the wafer by an elastic restoring force of the elastic element of each of the holding assemblies.

2. The wafer holding device of claim 1, wherein the support platform further comprises a plurality of guide holes, and each of the guide holes passes through from the first side to the second side; and wherein the base comprises a first component, a second component and a guide element, the first component being connected to the second component via the guide element, the guide element passing through the corresponding guide hole and being movable linearly in the guide hole, the first component being located on the first side, and the second component being located on the second side.

3. The wafer holding device of claim 2, wherein the base further comprises a third component, the third component being located on the second side and being adjustably coupled with the second component, and the first magnetic element being disposed on the third component.

4. The wafer holding device of claim 3, wherein the support platform further comprises a plurality of slide grooves, each of the slide grooves being disposed on the first side, and each of the guide holes passing through from a bottom surface of the slide groove to the second side; and wherein the base further comprises a sliding block, the sliding block being disposed on the first component and being slidable linearly in the corresponding slide groove.

5. The wafer holding device of claim 3, wherein the support platform further comprises a flow guide portion, the flow guide portion being disposed on the first side, and a fluid passage being formed between the flow guide portion and a surface of the first side.

6. The wafer holding device of claim 3, wherein the base further comprises a holding portion and a supporting portion, both the holding portion and the supporting portion being disposed on the first component.

7. The wafer holding device of claim 3, wherein the support platform further comprises a plurality of accommodating portions, the base of each of the holding assemblies comprising a corresponding accommodating portion, and the two ends of the elastic element of the holding assemblies being respectively engaged with one of the plurality of accommodating portions and the corresponding accommodating portion of the base.

8. The wafer holding device of claim 3, further comprising a plurality of quick-release elements, each of the quick-release elements being disposed on the second side and being configured such that the corresponding elastic element is sandwiched between the quick-release element and the support platform.

9. The wafer holding device of claim 1, wherein a first active surface of the first magnetic element and a second active surface of the at least one second magnetic element have the same polarity, the first magnetic element being farther from a central axis of the support platform than the at least one second magnetic element.

10. The wafer holding device of claim 1, wherein a first active surface of the first magnetic element and a second active surface of the at least one second magnetic element have the opposite polarities, the first magnetic element being closer to a central axis of the support platform than the at least one second magnetic element.

11. The wafer holding device of claim 1, wherein the elastic element is a flat spring.
